(19) United States
(12) Patent Application Publication
(10) Pub. No.: US 2026/0189123 A1
(43) Pub. Date: Jul. 2, 2026

(54) POWER SUPPLY

(71) Applicant: Renesas Electronics Corporation, Tokyo (JP)

(72) Inventor: Takahisa GUNJI, Tokyo (JP)

(21) Appl. No.: 19/430,983

(22) Filed: Dec. 23, 2025

Related U.S. Application Data
(60) Provisional application No. 63/739,290, filed on Dec. 27, 2024.

(30) Foreign Application Priority Data
Oct. 1, 2025 (JP) 2025-165350

(51) Int. Cl. H02M 1/00; H02M 1/08; H03K 7/08; H02M 1/15

(52) U.S. Cl. CPC H02M 1/0025; H02M 1/0012; H02M 1/08; H03K 7/08; H02M 1/15

(57) ABSTRACT

To provide a power supply device that includes a comparison circuit in the feedback circuit and employs an optical isolator in the voltage conversion unit. The power supply device comprises a switching circuit that controls the input voltage and converts it to output voltage, a power transmission unit that transmits the output voltage to the output stage, an optical isolator connected to the power transmission unit that transmits the voltage signal of the output stage to the feedback circuit while isolating it, and a feedback circuit that generates a control signal to control the switch based on the voltage signal input from the optical isolator and outputs it to the switching circuit, wherein the feedback circuit generates the control signal using a comparison circuit that binarizes the input voltage signal.

### CROSS-REFERENCE TO RELATED APPLICATIONS

The disclosure of U.S. Patent Provisional Application No. 63/739,290 filed on December 27, 2024, and Japanese Patent Application No. 2025-165350 filed on October 1, 2025, including the specification, drawings and abstract is incorporated herein by reference in its entirety.

### BACKGROUND

This disclosure relates to power supply units.

In view of the recent demand for miniaturization and widespread use of information devices, there is a need for inexpensive power circuits that are small, have high withstand voltage, and can be used in various environments such as under strong noise. The power circuit operates to convert the input voltage to a predetermined output voltage. Patent Document 1 describes a power supply unit equipped with an optical feedback circuit.

[Patent Document 1] Japanese Unexamined Patent Application Publication No. 2000-92829

### SUMMARY

However, simply replacing the magnetic feedback circuit with an optical feedback circuit results in oscillation where the output toggles between high and low. Therefore, the purpose of this disclosure is to provide a power supply unit that includes a comparison circuit in the feedback circuit and employs an optical isolator in the voltage conversion section.

One embodiment includes a feedback circuit that generates a control signal for switch control based on the voltage signal input from an optical isolator and outputs it to a switching circuit, where the feedback circuit generates the control signal using a comparison circuit that binarizes the input voltage signal.

One embodiment provides a power supply unit that includes a comparison circuit in the feedback circuit and employs an optical isolator in the voltage conversion section.

### BRIEF DESCRIPTION OF THE DRAWINGS

FIG. 1 is a block diagram showing the circuit configuration of a power supply unit related to comparative example.

FIG. 2 is a diagram showing the details of the feedback circuit of a power supply unit related to comparative example.

FIG. 3 is a diagram of the feedback signal of a magnetic voltage conversion circuit related to comparative example.

FIG. 4 is a diagram of the feedback signal of an optical voltage conversion circuit related to comparative example.

FIG. 5 is a block diagram showing the circuit configuration of a power supply unit related to comparative example and a block diagram showing the circuit configuration of the power supply unit according to this disclosure.

FIG. 6 is a block diagram showing the circuit configuration of the power supply unit according to this disclosure and a diagram showing an example of the area occupied by the circuit.

FIG. 7 is a diagram showing an example of the A/D conversion result of a magnetic power supply unit and the count result of the power supply unit according to this disclosure.

FIG. 8 is a diagram showing an example of the output voltage of the power supply unit according to this disclosure converging.

FIG. 9 is a diagram showing an example of the output voltage of a power supply unit related to comparative example and the output voltage of the power supply unit according to this disclosure.

FIG. 10 is a block diagram showing the circuit configuration of the power supply unit according to this disclosure.

FIG. 11 is a block diagram showing the second circuit configuration of the power supply unit according to this disclosure.

### DETAILED DESCRIPTION

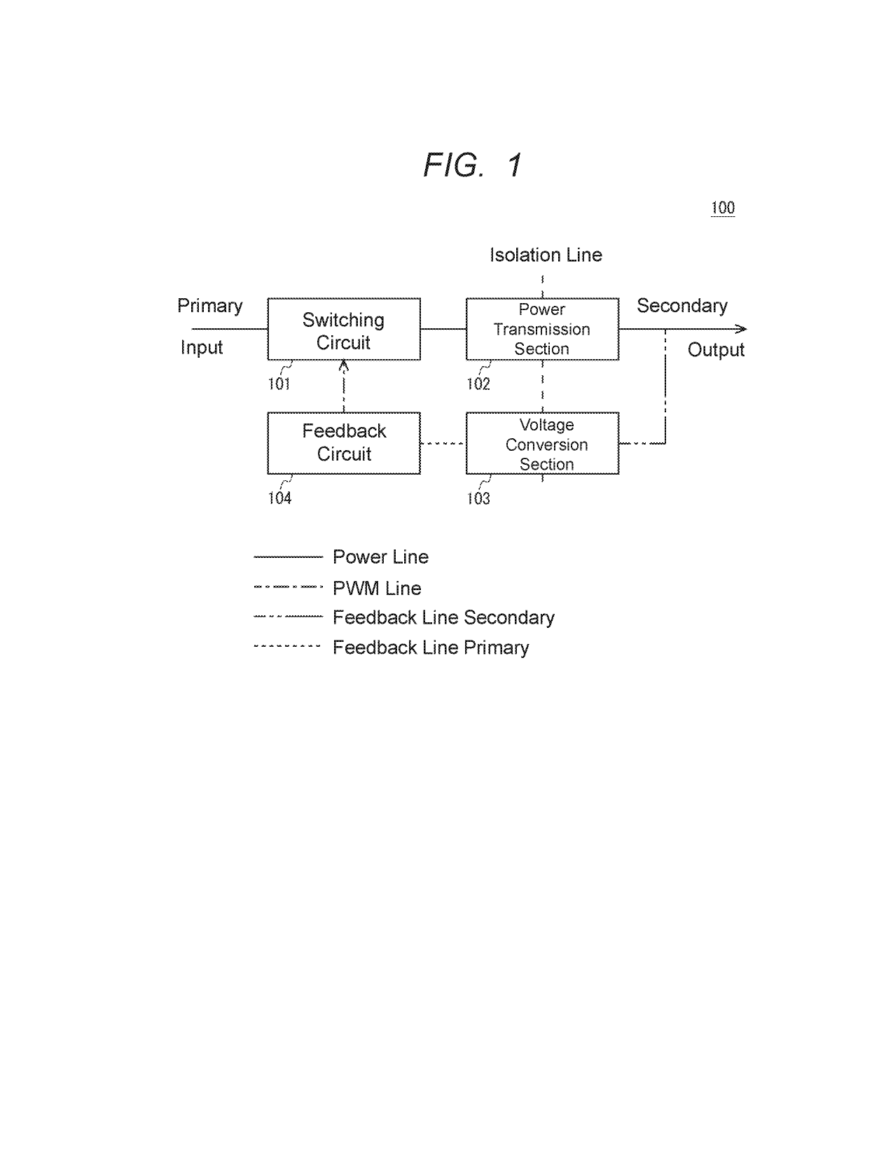

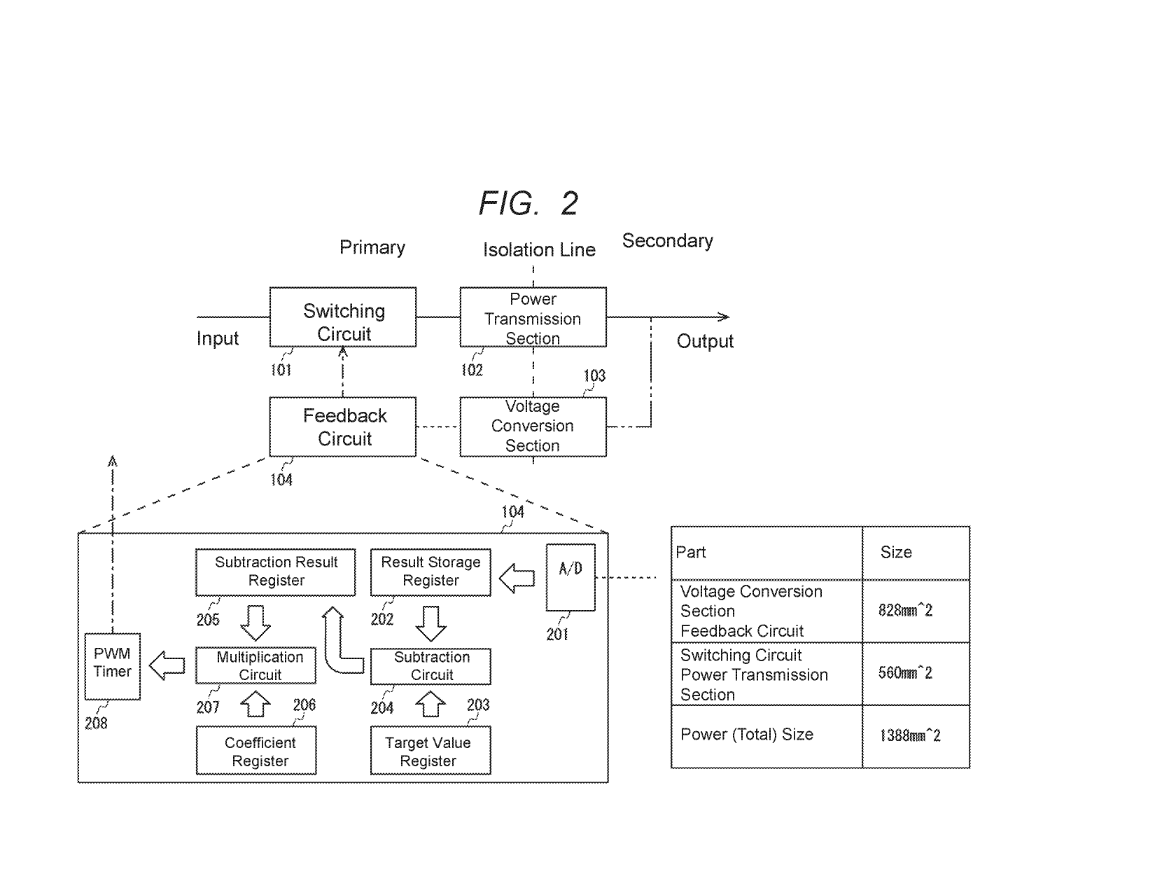

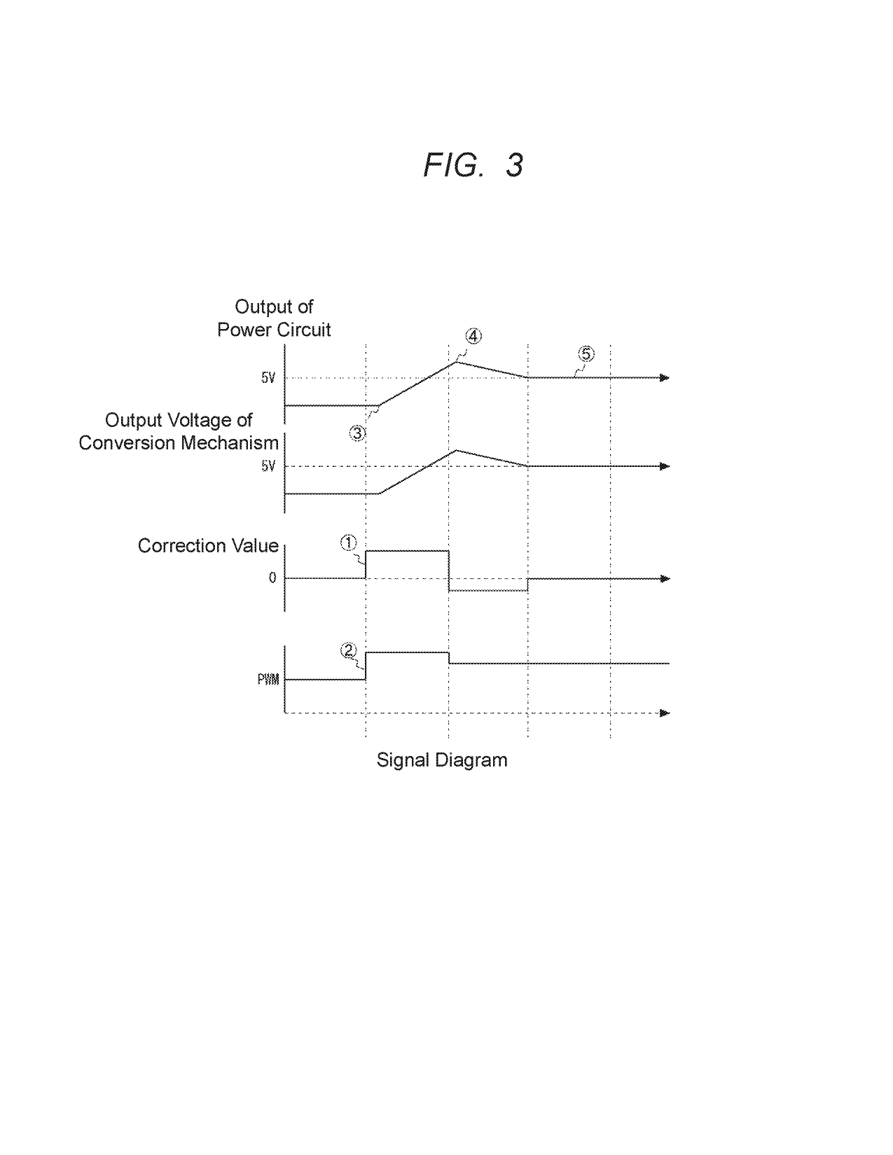

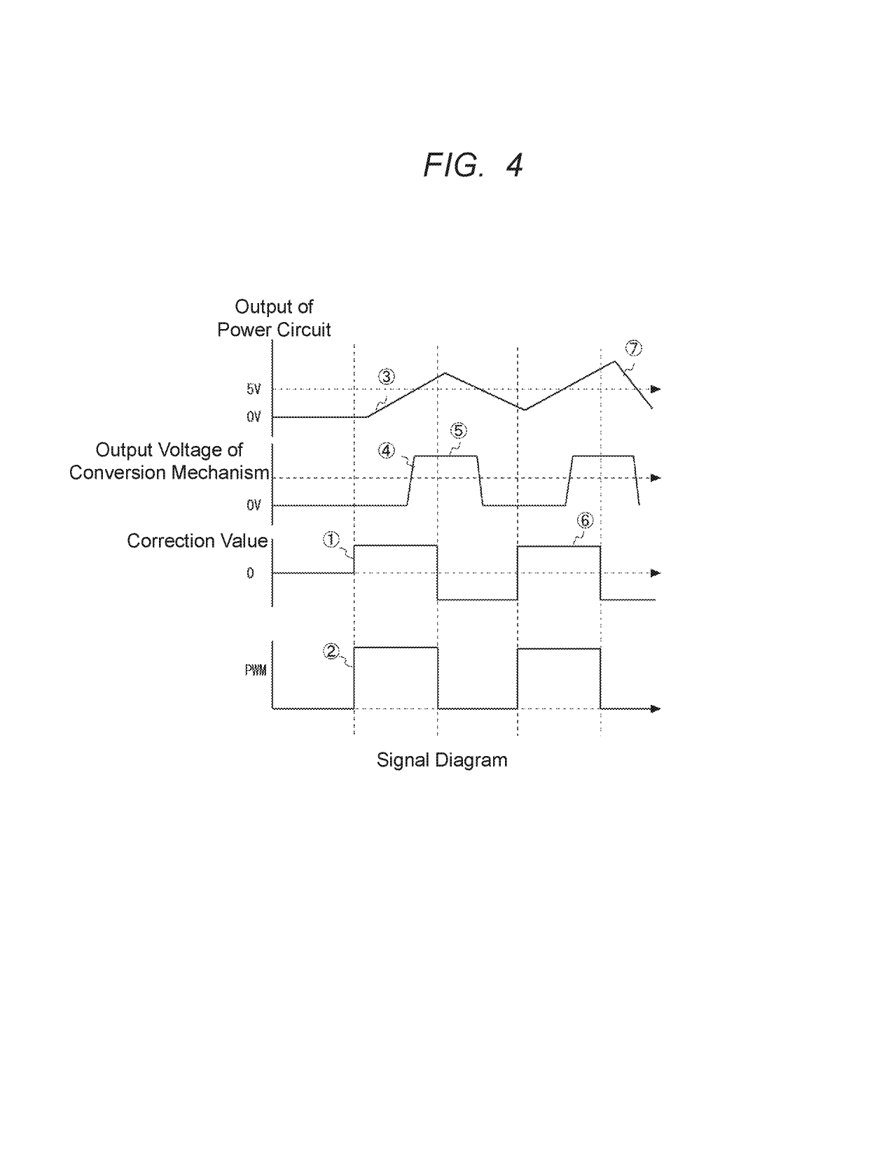

FIG. 1 is a block diagram showing the circuit configuration of a power supply unit related to comparative example. FIG. 2 is a diagram showing the details of the feedback circuit of a power supply unit related to comparative example. FIG. 3 is a diagram of the feedback signal of a magnetic voltage conversion circuit related to comparative example. FIG. 4 is a diagram of the feedback signal of an optical voltage conversion circuit related to comparative example. Referring to FIGS. 1 to 4, the power supply unit related to comparative example is described.

The internal configuration of the power supply unit 100 related to comparative example is described using the switching power supply method as an example. As shown in FIG. 1, the power supply unit 100 includes a switching circuit 101 for adjusting power, a power transmission section 102 which is a transformer, a voltage conversion section 103, and a feedback circuit 104.

The switching circuit 101 is a circuit for adjusting power and is controlled by the feedback circuit 104. That is, the switching circuit controls the input voltage by switching and converts it to the output voltage. The power transmission section 102 includes a transformer or the like and transmits the energy created by the switching circuit 101. That is, the power transmission section 102 transmits the output voltage to the output stage. The output stage indicates both the output to the external circuit and the output to the voltage conversion circuit.

The voltage conversion section 103 communicates the state of the output to the feedback circuit 104. The feedback circuit 104 monitors the difference between the output and the target value so that the output approaches the target value, and operates the switching circuit so that the difference becomes zero. Specifically, control is performed by adjusting the duty or frequency of the PWM (Pulse Width Modulator). In addition, the power supply unit 100 may require insulation due to safety standards or the like. In that case, insulation is performed between the power transmission section 102 and the voltage conversion section 103. There are magnetic and optical insulation methods. The magnetic method is realized by mutual induction using coils. The optical method uses a photocoupler that combines a light-emitting element such as an LED (Light Emitting Diode) and a light-receiving element such as a photodiode. The LED emits light with the input signal, and the light-receiving element receives the light and converts it into an electrical signal.

As a method of the feedback circuit 104, digital control methods using microcontrollers, which facilitate efficiency improvement and load characteristic improvement, are widespread. The feedback circuit 104 of the same method converts the output voltage obtained from the voltage conversion section 103 into a digital value, performs numerical calculation of the difference from the target value, calculates the correction value by multiplying by a coefficient, and reflects the result in the PWM duty.

As shown in FIG. 2, the feedback circuit 104 includes an A/D (Analog-Digital) converter 201, a result storage register 202, a target value register 203, a subtraction circuit 204, a subtraction result register 205, a coefficient register 206, a multiplication circuit 207, and a P (subtraction/multiplication) arithmetic circuit, and a PWM timer 208.

The operation of the feedback circuit 104 is described. The A/D converter 201 converts the feedback line signal, which is the output. Next, the subtraction circuit 204 calculates the difference between the target value and the output. Next, the multiplication circuit 207 multiplies the difference by a coefficient. The PWM timer 208 is changed according to the multiplication result. Changing the PWM timer 208 changes the output. The feedback circuit 104 is operated so that the difference between the target value and the output becomes zero. As a result, the output voltage stabilizes.

The area of the feedback circuit 104 is, for example, 828mm2 for the voltage conversion section 103 and the feedback circuit 104, 560mm2 for the switching circuit 101 and the power transmission section 102, totaling 1388mm2.

Referring to FIG. 3, the operation of the feedback function is described. If the actual output is 0V against the target output voltage of 5V, the correction value for the output is calculated as follows. The correction value is a relative amount operated by the feedback circuit on the switching circuit to bring the output closer to the target value. When A/D conversion value is 0, An error value Err is 5.0-0=5.0, and a correction amount P is Err×A.

Here, Err is the error value, which is the difference between the current value and the target. P is the correction value. A is a coefficient, which is a fixed value determined by the characteristics of the circuit or controller. If A is 1, then P=5.

As a result of the calculation, if the correction amount P is positive, control is performed to increase the output, and if negative, control is performed to decrease the output. If the absolute value of P is large, it is operated strongly, and if small, it is operated weakly. This is called proportional control.

In FIG. 3, at 1, the correction value is positively corrected by feedback calculation. At 2, the positive correction value is reflected in the PWM. At 3, the output increases due to the rise of the PWM. At 4, because the output has risen too much, the output is lowered in the next cycle. At 5, the output stabilizes. Thus, the output of the power supply unit 100 and the output voltage of the conversion mechanism are identical.

The magnetic power supply unit used in digital control has a linear input-output relationship, and it is possible to know how much deviation there is from the target value. Therefore, it is possible to calculate the correction value for the deviation and perform feedback operation to approach the target value. On the other hand, the magnetic power supply unit has a large physical area and cannot meet the demand for miniaturization of the power supply. Also, since the insulation withstand voltage is low, it cannot be used for equipment that requires high withstand voltage.

The optical power supply unit is characterized by being small and having high insulation withstand voltage, and is an insulation transmission method that can overcome the aforementioned problems. However, if the magnetic conversion mechanism is directly replaced with the optical conversion mechanism, the output becomes oscillation that toggles between high and low. This is because the optical input-output relationship is a nonlinear characteristic that indicates whether the output is higher or lower than the target value, and cannot express the amount of deviation from the target value like the magnetic method.

As shown in FIG. 4, the optical power supply device corrects the correction value positively through feedback calculation at point 1. At point 2, the positive correction value is reflected in the PMW. At point 3, the output increases due to the rise in PWM. At point 4, the output voltage of the conversion mechanism quickly sticks to high near the target voltage. At point 5, a full negative correction value is calculated for the output voltage of the conversion mechanism in the next cycle. As in point 6, the correction value constantly oscillates between its limits. As in point 7, the output becomes unstable.

The optical type has the characteristic that the output sticks to high when close to the target voltage and sticks to low when below the target voltage. Therefore, if the feedback circuit of related technology is used as is, the correction amount oscillates between maximum and minimum, causing the actual output to fluctuate around the target value and oscillate without converging.

### (Description of the power supply device according to Embodiment 1)

For clarity of explanation, the following descriptions and drawings are appropriately omitted and simplified. Furthermore, each element described in the drawings as functional blocks performing various processes can be configured with hardware such as a CPU (Central Processing Unit), memory, and other circuits, and can be implemented with software such as programs loaded into memory. And each of the hardware may be implemented as a component of a semiconductor device. Therefore, these functional blocks can be implemented by hardware, software operating on hardware, or a combination thereof. In the drawings, identical elements are assigned the same reference numerals, and redundant explanations are omitted as necessary.

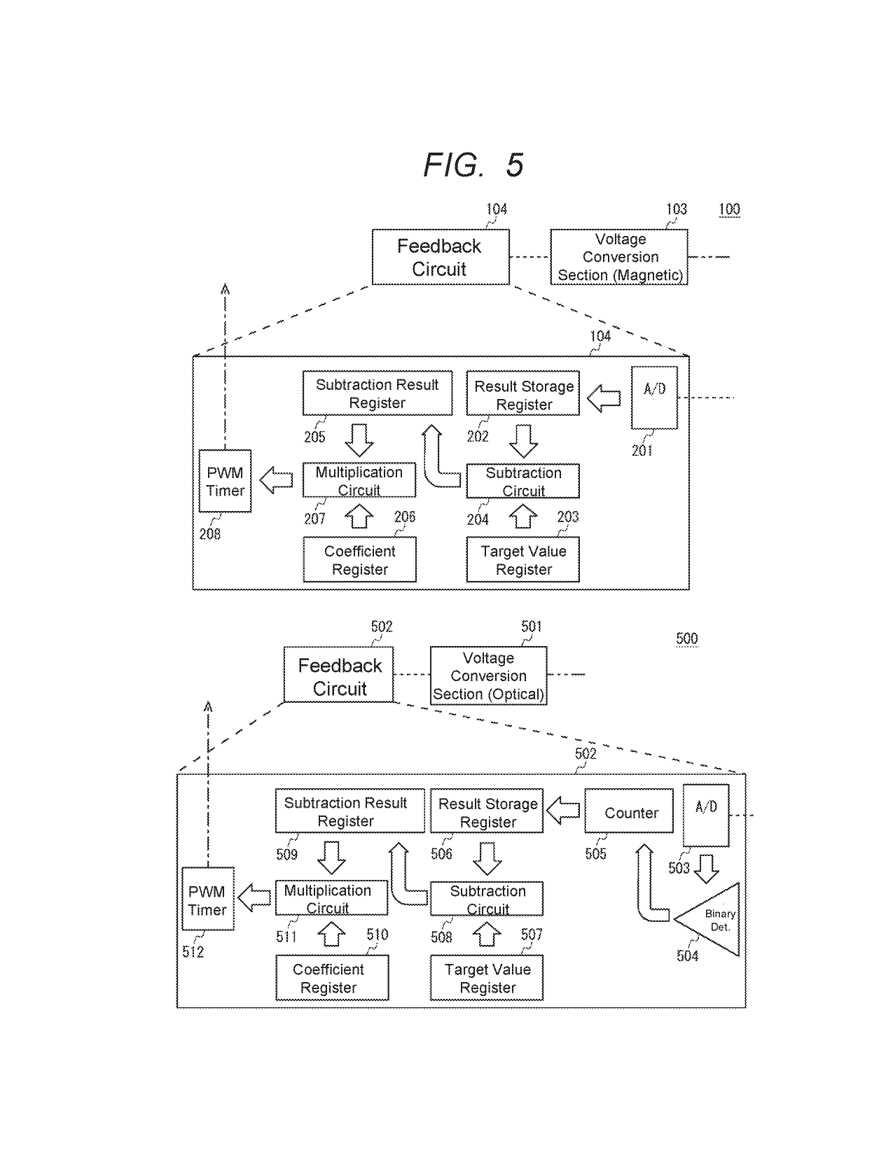

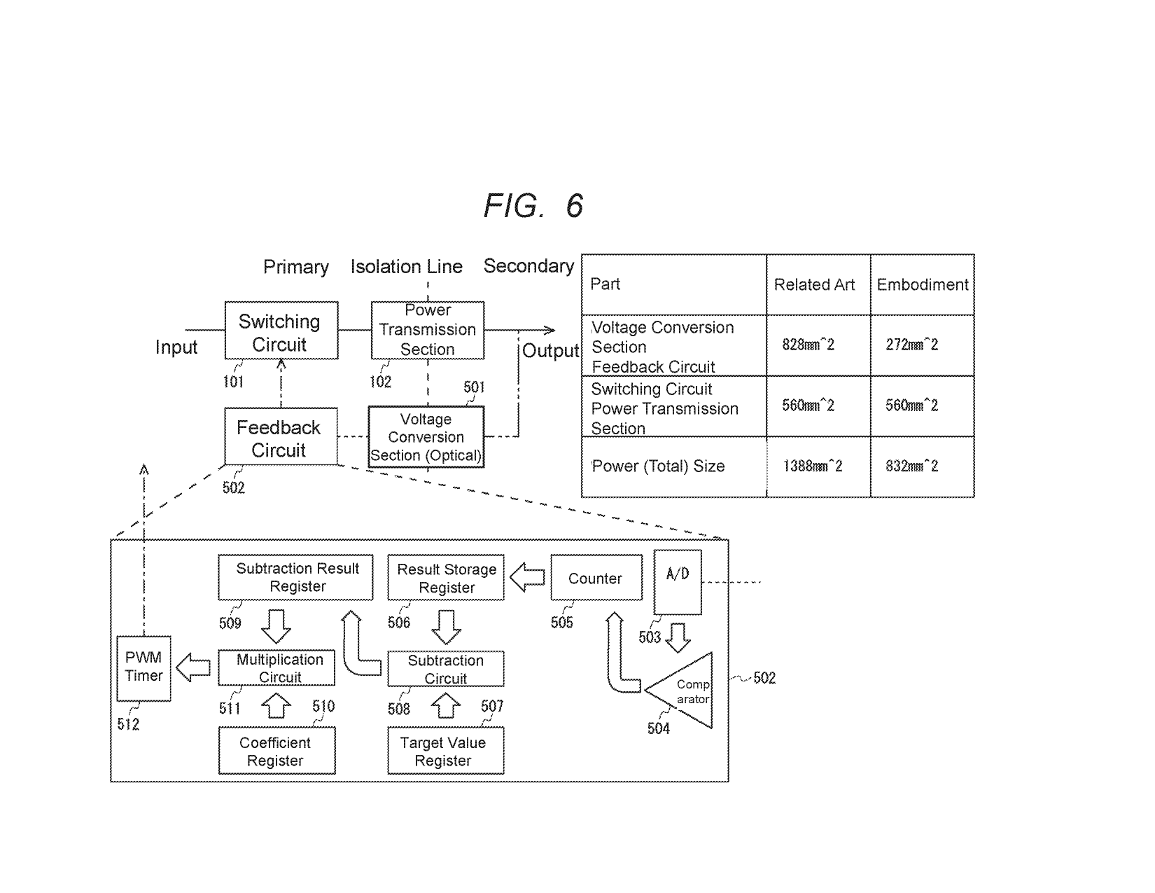

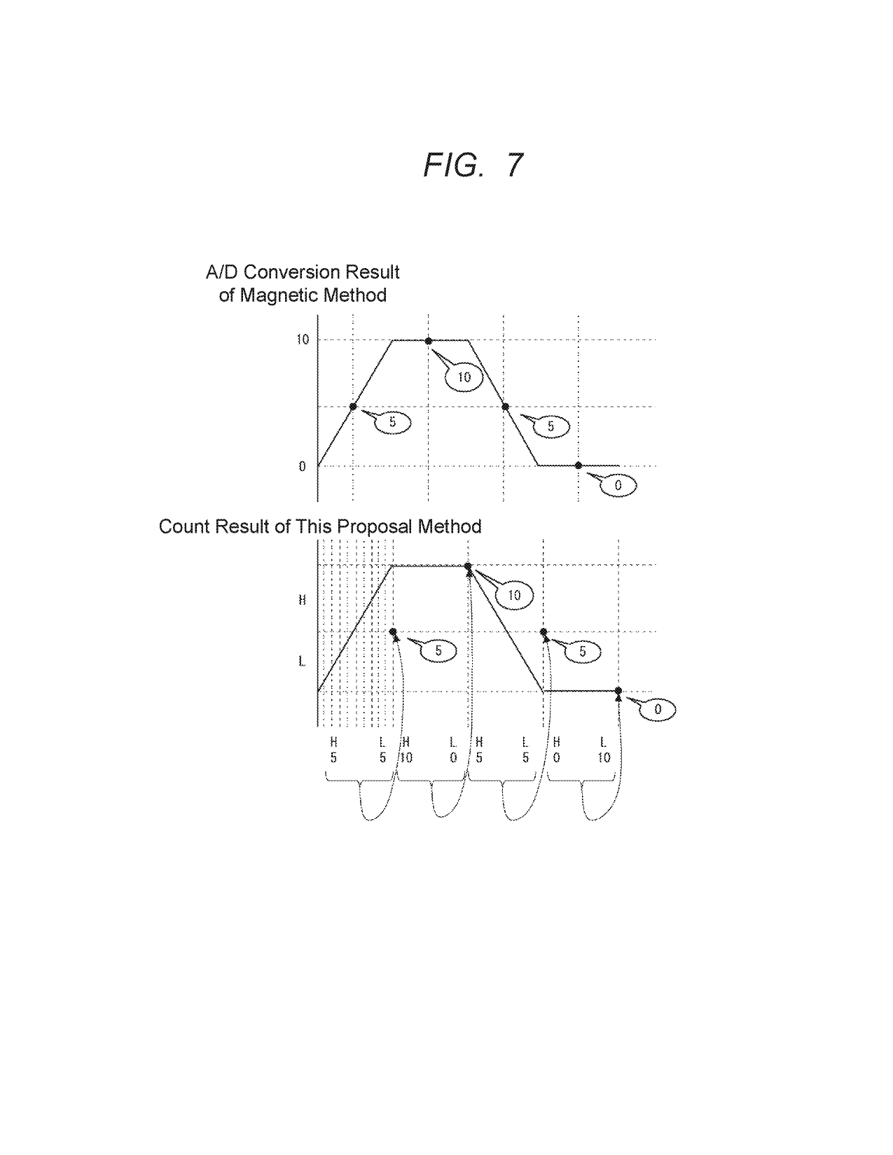

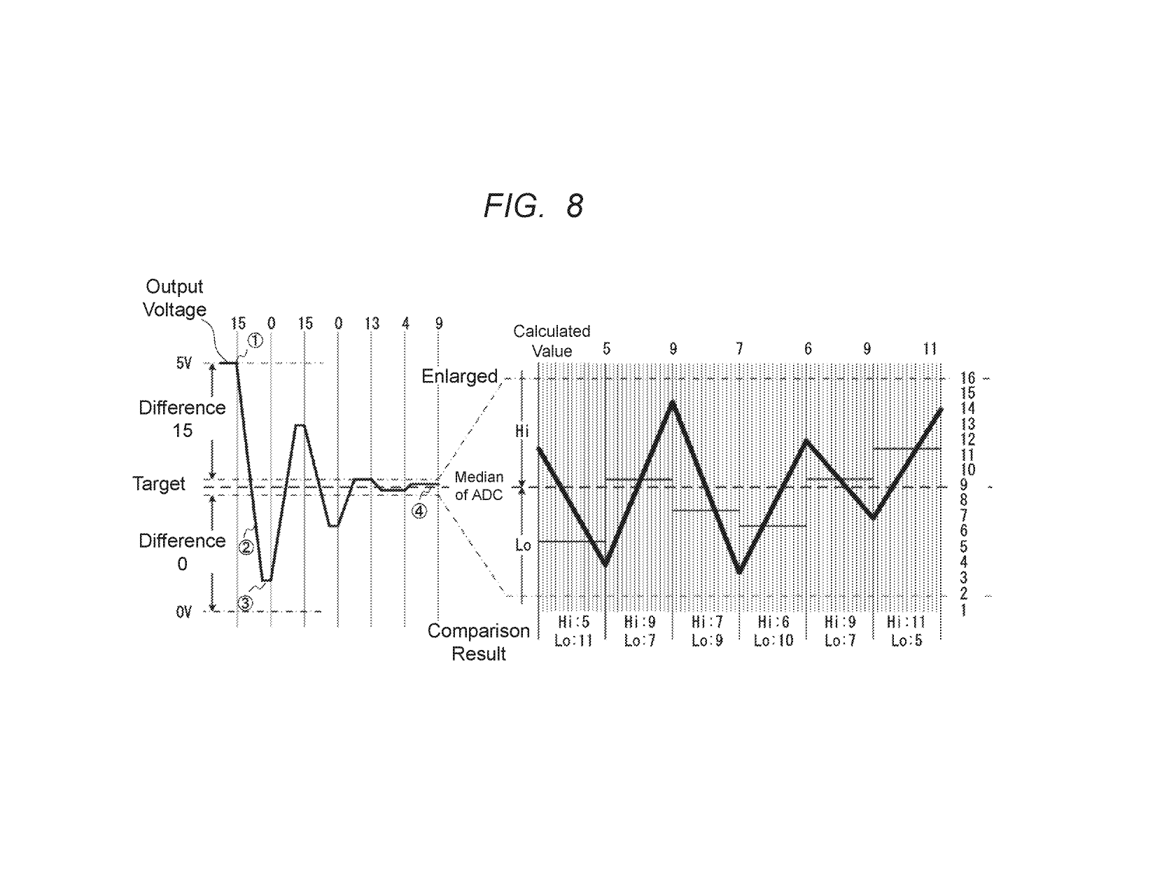

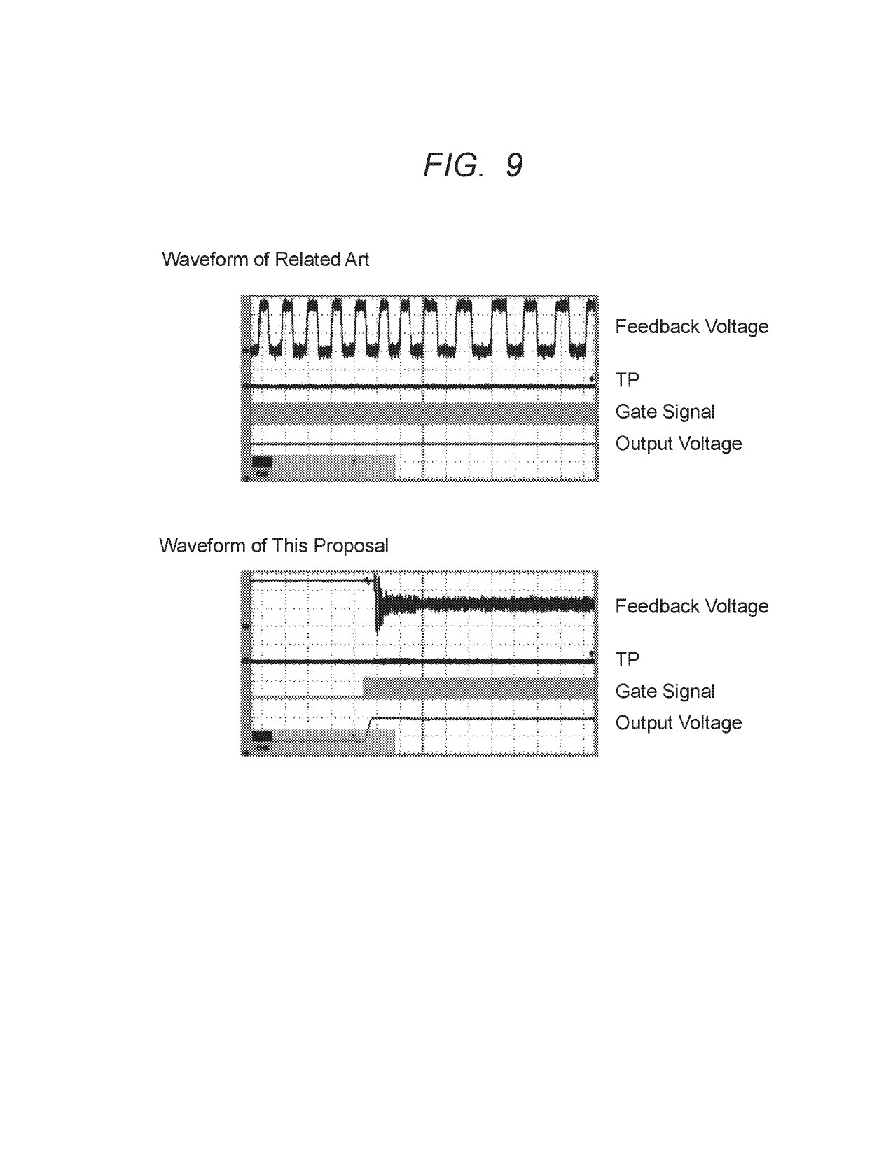

FIG. 5 is a block diagram showing the circuit configuration of a power supply device according to related technology and a block diagram showing the circuit configuration of the power supply device according to the present disclosure. FIG. 6 is a block diagram showing the circuit configuration of the power supply device according to the present disclosure and a diagram showing an example of the area occupied by the circuit. FIG. 7 is a diagram showing an example of the A/D conversion result of a magnetic power supply device and the count result of the power supply device according to the present disclosure. FIG. 8 is a diagram showing an example of the output voltage of the power supply device according to the present disclosure converging. FIG. 9 is a diagram showing an example of the output voltage of the power supply device according to related technology and the output voltage of the power supply device according to the present disclosure. Referring to FIGS. 5 to 9, the power supply device according to Embodiment 1 will be described. The power supply device according to Embodiment 1 is connected to the power supply of a display device, for example. The power supply device may also be used for other electrical appliances.

As shown in FIG. 5, the power supply device 500 according to Embodiment 1 differs in that it includes a power supply device 100 according to related technology, an optical voltage conversion unit 501, and a feedback circuit 502. The optical voltage conversion unit 501 is connected to the power transmission unit 102 and includes an optical isolator that transmits the voltage signal of the output stage to the feedback circuit 502 while isolating it. As mentioned earlier, the optical isolator includes a combination of a light-emitting element and a light-receiving element. The feedback circuit 502 generates a control signal for switch control based on the voltage signal input from the optical isolator and outputs it to the switching circuit.

Additionally, the feedback circuit 502 includes a P (subtraction/multiplication) arithmetic circuit comprising an A/D converter 503, a comparison circuit 504, a counter circuit 505, a result storage register 506, a target value register 507, a subtraction circuit 508, a subtraction result register 509, a coefficient register 510, and a multiplication circuit 511, as well as a PWM timer 512.

The output of the voltage conversion unit 501 through a general A/D converter 503 is determined by the comparison circuit 504. The comparison circuit 504 uses a comparator to binarize and determine the output. The binary comparison result counted by the counter circuit 505 is integrated over the feedback cycle time to obtain the difference from the target value. By inputting this result into the existing feedback circuit, a stable output can be obtained.

As shown in FIG. 6, the A/D converter 503 converts the output analog signal into a digital signal. The comparison circuit 504 binarizes and determines the output digital signal. The counter circuit 505 counts the comparison result determined by binarization. The counter circuit counts, for example, three positives and four negatives. The result storage register 506 stores the counted results. The target value register 507 stores the target value, so the subtraction circuit 508 subtracts the counted result from the target value. The result of the subtraction is stored in the subtraction result register 509. Since the coefficient A specific to the circuit is stored in the coefficient register 510, the multiplication circuit 511 multiplies the difference by the coefficient A. The result of the multiplication is output to the PWM timer 512, which generates a control signal for switch control. The control signal is sent to the switching circuit 101, which controls the output.

In this way, the count value is used as the difference from the target value. Additionally, binary determination is performed, the number of determinations is increased, and feedback cycle time integration is performed to detect output fluctuations.

As a result, the area of the power supply device 500 according to the embodiment is 272mm2 for the voltage conversion unit 501 and feedback circuit 502, and 560mm2 for the switching circuit 101 and power transmission unit 102, totaling 832mm2. The area of the power supply device 500 according to the embodiment is smaller than the 1388mm2 of the power supply device 100 according to related technology.

As shown in FIG. 7, the magnetic A/D conversion result yields analog values of 5V, 10V, 5V, and 0V. The count result of the present disclosure is represented by the total count value over a certain period. For example, in the first period, since high (H) is 5 and low (L) is 5, a value of 5V is obtained. In the next period, if H is 10, a value of 10V is obtained. In the next period, since H is 5 and L is 5, a value of 5V is obtained. In the next period, since L is 10, a value of 0V is obtained. Thus, the magnetic method and the method of the present disclosure yield the same values. The count is calculated by obtaining the time average.

The determination of H or L is made using a 12-bit A/D converter:

12bit = 4095 counts = 10V, and 0 count = 0V

Therefore, it is determined whether it is 2048 or more or less.

The count value for the first period is calculated as L for the first measurement since it was 2048 or less, L for the second measurement... and H 5 times, L 5 times for 10 measurements.

As shown in FIG. 8, the output converges to the target value. If the counter value of the binary determination result is positive as in point 1, the result of the P arithmetic circuit is calculated to lower the output as in point 2. As in point 3, in the next unit time, if the output is lowered too much, it moves to raise it next. Repeating this process causes convergence around the target value as in point 4.

As shown in FIG. 9, the waveform of the FB (Feedback) voltage of related technology using the microcontroller's A/D conversion value directly for feedback is unstable, repeating minimum and maximum values. When the microcontroller's A/D conversion value is input to the comparator, the waveform of the FB voltage of the present disclosure converges.

With the above configuration, a power supply device is provided that includes a comparison circuit in the feedback circuit and employs an optical isolator in the voltage conversion unit.

### (Description of the power supply device according to Embodiment 2)

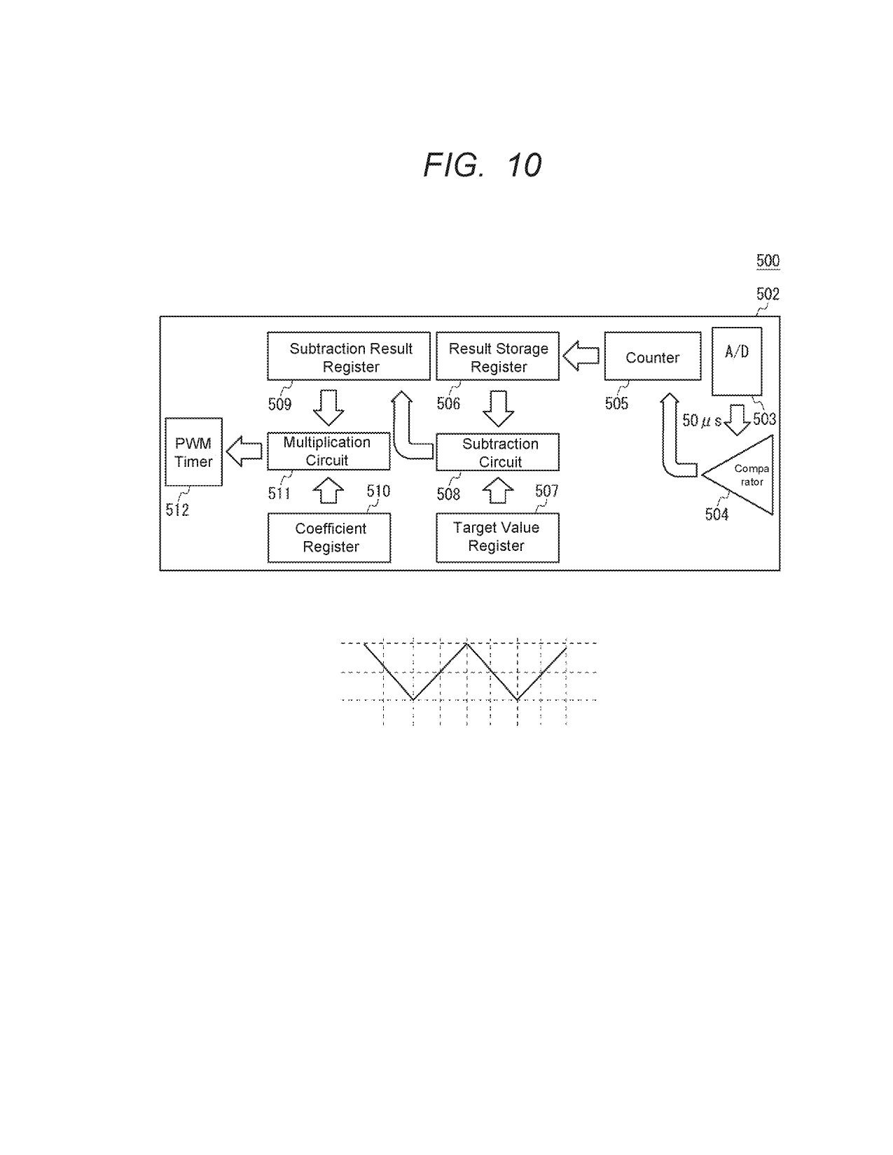

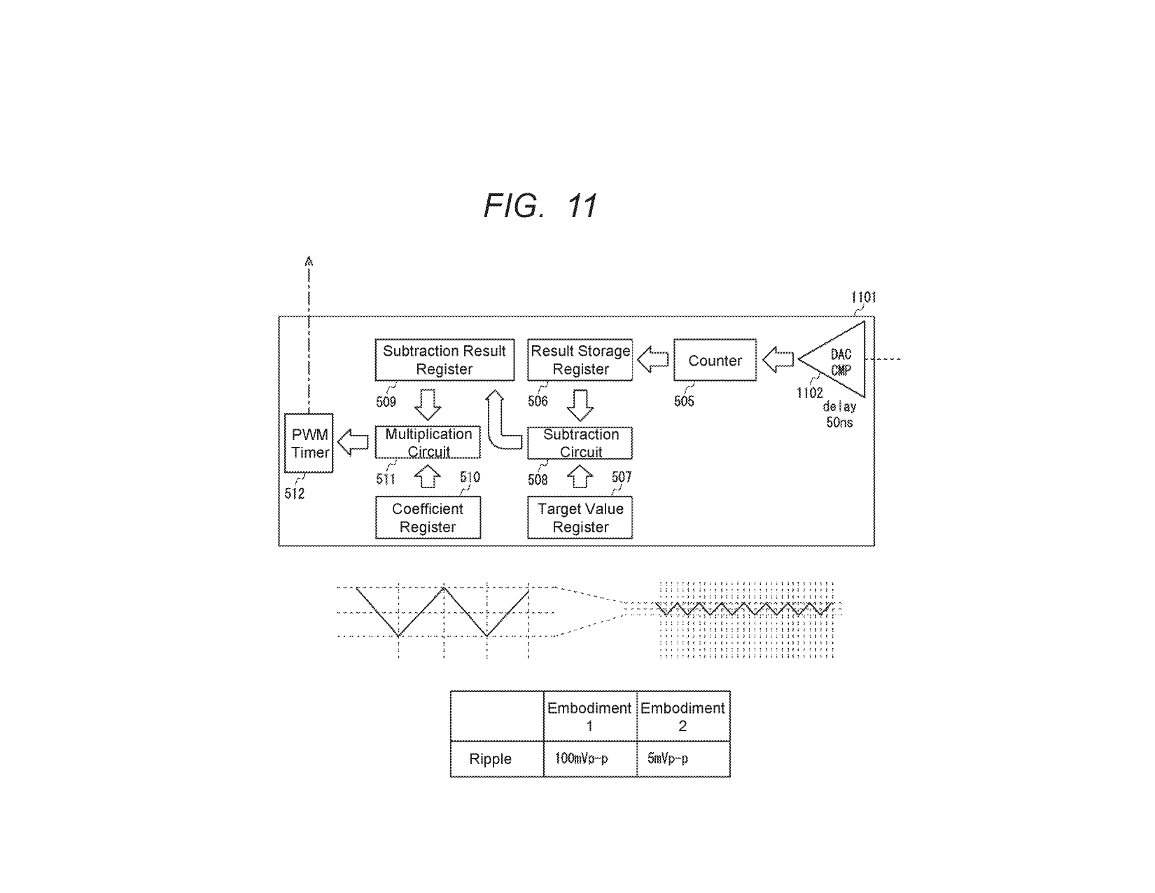

FIG. 10 is a block diagram showing the circuit configuration of the power supply device according to the present disclosure. FIG. 11 is a block diagram showing the second circuit configuration of the power supply device according to the present disclosure. Referring to FIGS. 10 and 11, the power supply device according to Embodiment 2 will be described.

The feedback circuit 502 of the power supply device 500 according to Embodiment 1 shown in FIG. 10 operates by integrating the result of the A/D converter 503 over the feedback period. In this case, since the conversion of the A/D converter takes about 1μs, a response time of about 50μs was required.

This means that even if the delay outside the feedback circuit 104 is zero, a response cannot be made within 50μs. Therefore, even if the output exceeds the target value, it cannot be corrected until the next cycle, and as shown in the lower diagram of FIG. 10, a corresponding ripple occurs in the result output.

As shown in FIG. 11, since binary output is sufficient, the feedback circuit 1101 of the power supply device according to Embodiment 2 replaces the A/D converter 503 and comparison circuit 504 with a combination of a comparator and D/A (digital-to-analog) converter 1102.

The comparator converts the output into binary based on its magnitude. The D/A converter outputs a reference voltage for binary determination to the comparator. The counter circuit 505 counts the H or L signal output from the comparator.

Compared to the A/D converter speed of 1μs, the comparator speed is 50ns, making it 20 times faster. The response time to the PWM timer can be shortened, and as shown in the table, the ripple can be reduced from 100mVp-p to 5mVp-p, minimizing the fluctuation range of the output voltage.

It should be noted that the present invention is not limited to the above embodiments and can be appropriately modified without departing from the spirit of the invention.

What is claimed is:

1. A power supply device comprising:
a switching circuit that controls an input voltage and generates an output voltage based on the input voltage,
a power transmission circuit that transmits the output voltage to an output stage,
an optical isolator connected to the power transmission circuit that isolates and transmits the voltage signal of the output stage,
a feedback circuit that generates a control signal to control the switching circuit based on the voltage signal transmitted from the optical isolator and outputs the control signal to the switching circuit,
wherein the feedback circuit generates the control signal using a comparison circuit that binarizes the input voltage signal.

2. The power supply device according to claim 1,
wherein the feedback circuit includes:
an A/D conversion circuit that converts the voltage signal into a digital signal,
a comparison circuit that performs binary determination on the digital signal,
a counter circuit that counts the comparison result of the comparison circuit.

3. The power supply device according to claim 1,
wherein the feedback circuit includes:
a comparison circuit and D/A conversion circuit that binarize the voltage signal,
a counter circuit that counts the binarized voltage signal.

4. The power supply device according to claim 3,
wherein the feedback circuit further includes,
a result storage register that stores the count result of the counter circuit,
a target value register that stores the target value of the count,
a subtraction circuit that subtracts the count result from the target value,
a subtraction result register that stores the result of the subtraction,
a coefficient register that stores the multiplication factor of the subtraction,
a multiplication circuit that multiplies the result of the subtraction by the multiplication factor, a PWM Timer that converts the result of the multiplication circuit into a PWM (Pulse Width Modulator) control signal.

5. The power supply device according to claim 1, wherein the optical isolator comprises a light-emitting element and a light-receiving element.
